(19) United States
(12) Patent Application Publication
(10) Pub. No.: US 2004/0218361 A1
(43) Pub. Date: Nov. 4, 2004

(54) Function module with built-in plate-type heat dissipation device

(76) Inventors: Wen-Yen Lin, Taoyuan City (TW); Tsan-Nan Chien, Taipei City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/824,223

(22) Filed: Apr. 14, 2004

(30) Foreign Application Priority Data
Apr. 29, 2003 (TW) 92109979

(51) Int. Cl. H05K 7/20

(52) U.S. Cl. 361/695

(57) ABSTRACT

A function module with a built-in plate-type heat dissipation device. The function module includes a first circuit board, a second circuit board, and a plate-type heat dissipation device. The first circuit board includes a first surface with a first ground layer formed thereon. The second circuit board is coupled to the first circuit board, and includes a second surface facing the first surface. A second ground layer is formed on the second surface. The plate-type heat dissipation device is disposed between the first circuit board and the second circuit board, and abuts the first ground layer and the second ground layer respectively.

### BACKGROUND OF THE INVENTION

1. Field of the Invention

The invention relates to a function module; in particular, to a function module with a built-in plate-type heat dissipation device.

2. Description of the Related Art

Generally, a printed circuit board of an electronic apparatus includes many electronic devices and operation circuits distributed thereon. When the electronic apparatus is operated, these electronic devices will produce heat further increasing temperatures inside the electronic apparatus such that the electronic device cannot be efficiently operated. When temperature increases too much, the device may malfunction. Therefore, a heat dissipation device is necessary on the printed circuit board for dissipating heat produced.

In addition, as the technology of semiconductor process has developed dramatically, the operating speeds thereof increase accordingly, such that a single electronic device may incorporate multiple functions. However, due to such design, it is difficult to simultaneously control heat dissipation, signal quality, and electromagnetic radiation in the electronic device.

As stated above, electronic devices communicate via the circuit board. In a computer system, electronic devices, such as central processor unit (CPU), chipset, graphics processing unit (GPU), accelerated graphics port (AGP), or dynamic random access memory (DRAM), are disposed in different areas of a motherboard. To solve heat dissipation problems for each electronic device, a conventional solution is provided for each electronic device.

For example, a combination of a heat dissipation fin, a heat pipe, and a fan is usually used for the CPU. The heat dissipation fin and/or the fan are usually used for the chipset or the GPU. However, the conventional solution cannot sufficiently solve the heat dissipation problem of a motherboard with a plurality of electronic devices thereon. Thus, a heat dissipation device with better efficiency is required. However, such solutions are conventionally only suitable for use on a flat surface. That is, the varying heights of each electronic device rule out the disposition of the conventional heat dissipation device on the PCB. Thus, disposition of the heat dissipation device on a PCB with varied height surface remains a problem.

### SUMMARY OF THE INVENTION

In view of this, a function module with a built-in plate-type heat dissipation device is provided. The function module includes a first circuit board, a second circuit board, and a plate-type heat dissipation device. The first circuit board includes a first surface with a first ground layer formed thereon. The second circuit board is coupled to the first circuit board, and includes a second surface facing the first surface. A second ground layer is formed on the second surface. The plate-type heat dissipation device is disposed between the first circuit board and the second circuit board abutting the first ground layer and the second ground layer respectively.

In a preferred embodiment, the first circuit board further includes a third surface, opposite to the first surface, with a first device located thereon.

In another preferred embodiment, the second circuit board further includes a fourth surface, opposite to the second surface, with a second device located thereon.

It is understood that both the first ground layer and the second ground layer may be made of copper.

In another preferred embodiment, the function module further includes a flat cable connecting the first circuit board and the second circuit board, providing communicability therebetween.

In another preferred embodiment, the first circuit board includes a first connector, and the second circuit board includes a second connector corresponding to the first connector. The first circuit board and the second circuit board communicate with each other by the respective connectors.

Furthermore, the first connector is located on the first surface, and the second connector is located on the second surface.

In another preferred embodiment, the function module further includes a slot connector connecting the first circuit board and the second circuit board, providing communicability therebetween.

It is understood that the plate-type heat dissipation device may be a plate-type heat pipe, a copper plate, a plate-type copper block, a micro fin, a water-cooling device, or a vapor chamber.

In another preferred embodiment, the function module further includes a heat dissipation fin, connecting to the plate-type heat dissipation device, for introducing heat on the function module to the surrounding.

Furthermore, the function module further includes a fan, connecting to the heat dissipation fin, for introducing heat on the function module to the surrounding.

In another preferred embodiment, the function module further includes a first adhesion layer and a second adhesion layer. The first adhesion layer is disposed between the plate-type heat dissipation device and the first ground layer, and the second adhesion layer is disposed between the plate-type heat dissipation device and the second ground layer, the adhesion layers attaching the respective surfaces to each other.

It is understood that both the first adhesion layer and the second adhesion layer may be made of brazing solder, tin solder, thermal interface material, or grease.

In this invention, another function module with a built-in plate-type heat dissipation device is provided. The function module includes a first circuit board, a second circuit board, and a plate-type heat dissipation device. The first circuit board includes a first surface, and a first heat conduction layer is formed on the first surface. The second circuit board is coupled to the first circuit board, and includes a second surface facing the first surface. A second heat conduction layer is formed on the second surface. The plate-type heat dissipation device is disposed between the first circuit board and the second circuit board in a manner such that the plate-type heat dissipation device is abutted by the first heat conduction layer and the second heat conduction layer respectively.

In a preferred embodiment, the first heat conduction layer is a ground layer of the first circuit board, and the second heat conduction layer is a ground layer of the second circuit board.

### BRIEF DESCRIPTION OF THE DRAWINGS

The present invention can be more fully understood by reading the subsequent detailed description and examples with references made to the accompanying drawings, wherein:

FIG. 1a is a schematic view of a function module as disclosed in this invention;

FIG. 1b is a side view showing the function module in FIG. 1a;

FIG. 2 is a schematic view showing a plate-type heat dissipation device disposed on the function module in FIG. 1b;

FIG. 3 is a schematic view showing the plate-type heat dissipation device and a height-compensation device disposed on the function module in FIG. 1b;

FIG. 4 is a schematic view of another function module as disclosed in this invention;

FIG. 5a is a schematic view showing a first circuit board and a second circuit board of another function module as disclosed in this invention;

FIG. 5b is an exploded view of the function module in FIG. 5a;

FIG. 5c is a schematic view of the assembled function module in FIG. 5b;

FIG. 5d is a side view of a varied embodiment of the assembled function module in FIG. 5b;

FIG. 6a is a schematic view of another embodiment of a function module as disclosed in this invention;

FIG. 6b is a schematic view of a second circuit board in FIG. 6a;

FIG. 6c is a schematic view of a first circuit board in FIG. 6a;

FIG. 7a is an exploded view of another embodiment of a function module as disclosed in this invention;

FIG. 7b is a side view of the assembled function module in FIG. 7a;

FIG. 8a is a cross section of a built-up circuit board; and

FIG. 8b is a cross section of a circuit board with a through hole.

### DETAILED DESCRIPTION OF THE INVENTION

As the operating speed of electronic devices increases, the transmission speed of the front side bus (FSB) of the computer increases to 800 MHz from 333 MHz. Thus, a single chip may incorporate multiple functions. Specifically, the electronic device, such as a CPU, a north bridge, or a GPU, located on the front side bus is provided with multiple functions.

Accordingly, it is difficult to simultaneously control heat dissipation, signal quality, and electromagnetic radiation in the electronic device. Thus, it is difficult to design the front side bus on the motherboard. In addition, the number of pins of the electron device increases accordingly. Thus, a high density interconnect (HDI) is provided as the circuit board of the computer system.

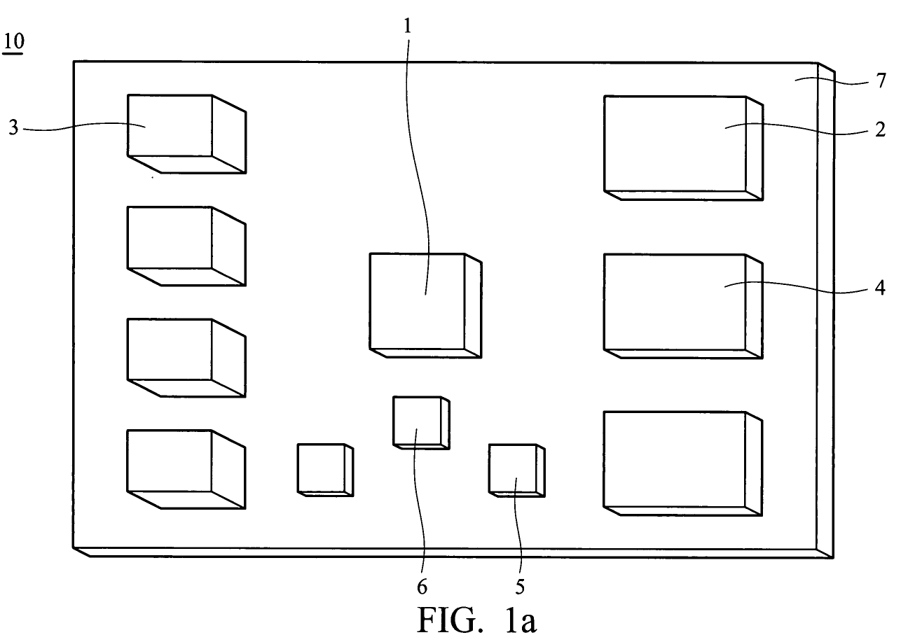

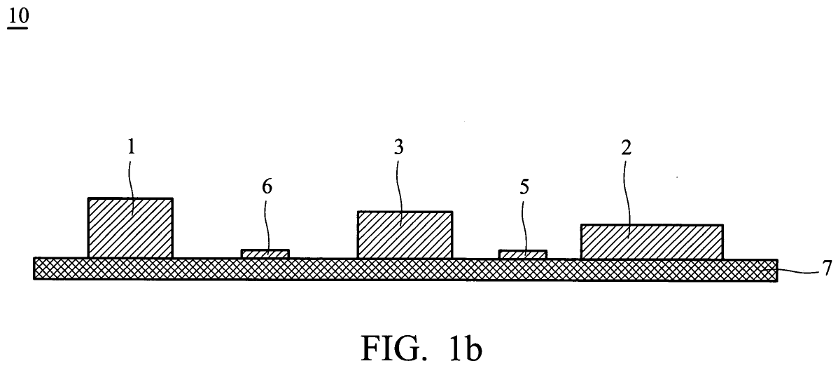

A function module, as disclosed in this invention, is provided with the above high-speed and high-density devices, solving heat dissipation problems thereof. Referring to FIG. 1a and FIG. 1b, electronic devices with high speed transmission such as, CPU 1, north bridge 2, GPU or AGP 3, DRAM 4 or GRAM (not labeled), are disposed on a HDI 7. Via the HDI 7, the high speed devices communicate with each other to constitute an independent function module 10. The function module 10 can be coupled to a printed circuit board with other devices via a connector, a flat cable, or solder, to constitute a complete motherboard of the computer. Thus, problems created by high speed devices are solved, and costs effectively reduced.

However, when all the high speed devices are disposed on the function module, heat originally generated on the motherboard, is also concentrated on the function module. Furthermore, since the high speed devices are disposed in a relatively small area, it is difficult to provide heat-dissipation for each device. Thus, the plate-type heat dissipation device, such as a plate-type heat pipe, a copper plate, a plate-type copper block, a micro fin, a water-cooling device, or a vapor chamber, is utilized in this invention to provide adequate heat-dissipation for each device on the function module.

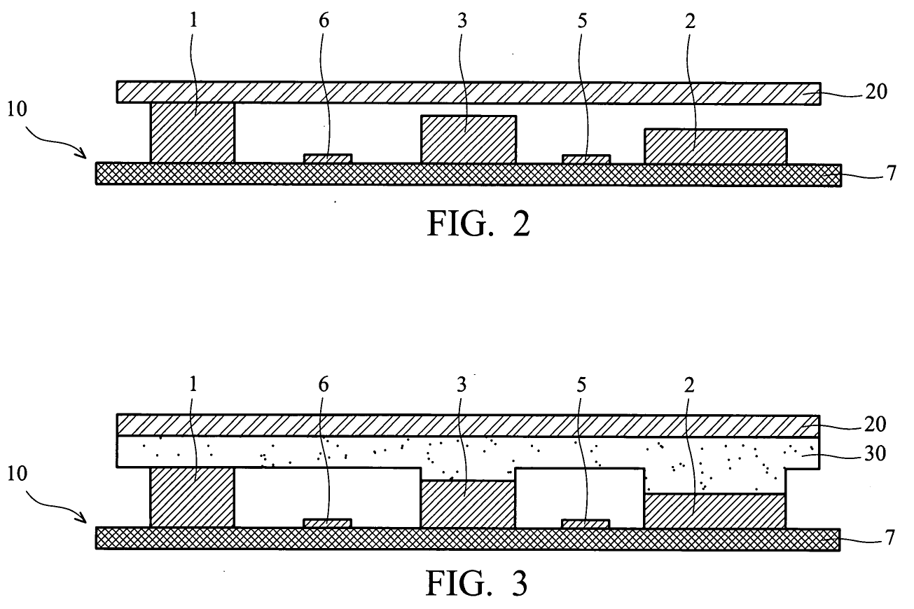

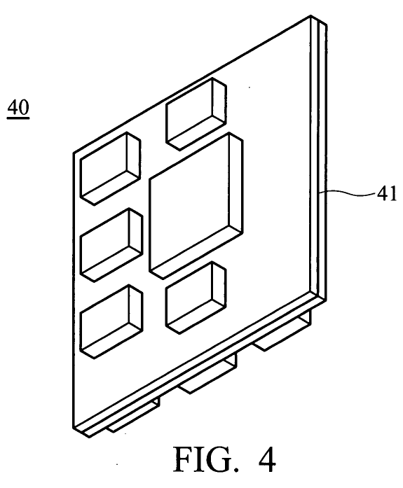

Referring to FIG. 2, a plate-type heat dissipation device 20 is disposed on the function module 10 including the CPU 1, the north bridge 2, the GPU 3, the DRAM 4, a resistor 5, a capacitor 6, and the HDI 7. Since the device heights are different, the plate-type heat dissipation device 20 cannot dissipate heat from every device. To solve this height differential, a height-compensation device 30 is disposed on the function module as shown in FIG. 3. The height-compensation device 30 is thermally connected to each of the main devices, such as the CPU 1, the north bridge 2, and the GPU 3, and the plate-type heat dissipation device 20 is disposed on the height-compensation device 30.

In addition, referring to FIG. 4, another function module 40 of the invention is shown. For a function module with more devices or with devices having different functions, the devices can be disposed on both surfaces of the function module 40 according to function. For example, devices can be disposed on the surfaces of the function module 40 by surface mount technology (SMT). To promote quality of the high frequency signal and provide supply of electricity, a ground layer 41 is disposed in the function module 40. When the plate-type heat dissipation device 20 as shown in FIG. 2 is disposed on the function module 40, the height-compensation device 30 as shown in FIG. 3 can be disposed therebetween. Thus, the height-compensation device 30 can be thermally connected to the main devices on the function module 40 so that the plate-type heat dissipation device 20 can effectively provide adequate heat dissipation for function module 40.

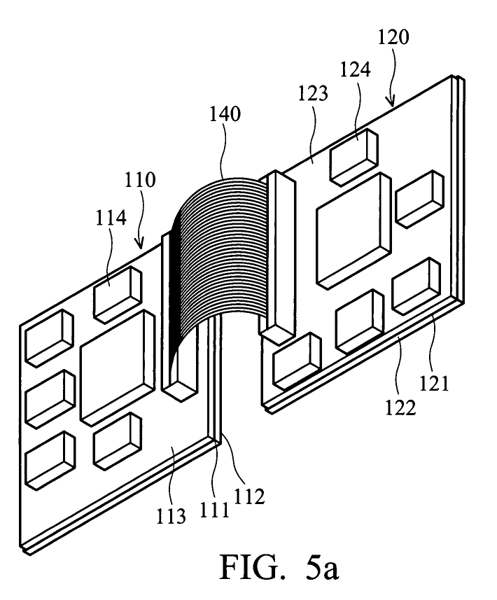

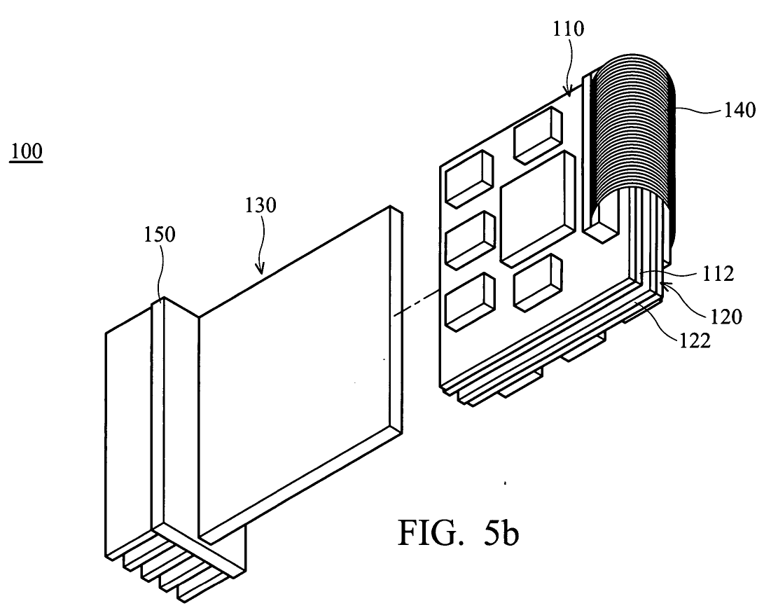

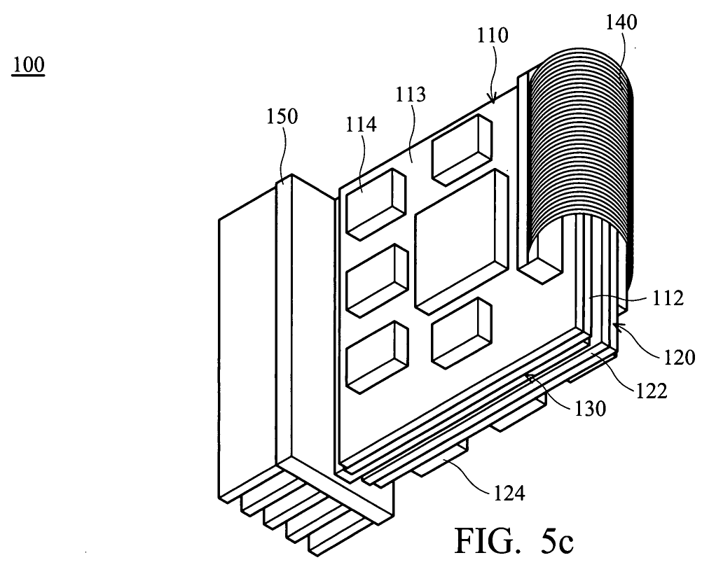

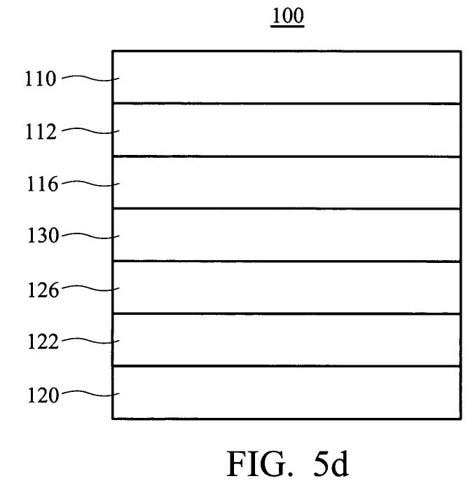

To effectively dissipate heat therefrom, the function module 40 as shown in FIG. 4 can be modified to more effectively utilize the plate-type heat dissipation device. FIGS. 5a-5c show another function module 100, with a built-in plate-type heat dissipation device, as disclosed in this invention. It is understood that the function module 100 is designed based on the function module 40 as shown in FIG. 4. Specifically, the function module 40 is divided into two circuit boards.

Referring to FIGS. 5a-5c, the function module 100 includes a first circuit board 110, a second circuit board 120, a plate-type heat dissipation device 130, and a flat cable 140. Both the first circuit board 110 and the second circuit board 120 may be made of HDI. As shown in FIG. 5a, the first circuit board 110 includes a first surface 111 and a third surface 113 opposite to the first surface 111. A first ground layer 112 is formed on the first surface 111, and a plurality of first devices 114 is disposed on the third surface 113. The first ground layer 112 is used as a heat conduction layer for the first circuit board 110. Thus, heat from the first circuit board 110 is quickly and uniformly conducted to the plate-type heat dissipation device 130. It is understood that the first ground layer 112 may be made of copper.

As shown in FIG. 5b, the second circuit board 120 is coupled to the first circuit board 110 via the flat cable 140, and includes a second surface 121, facing the first surface 111, and a fourth surface 123 opposite to the second surface 121. A second ground layer 122 is formed on the second surface 121, and a plurality of second devices 124 is disposed on the fourth surface 123. The second ground layer 122 is used as a heat conduction layer of the second circuit board 120. Thus, heat from the second circuit board 120 can be quickly and uniformly conducted to the plate-type heat dissipation device 130. It is understood that the second ground layer 122 may be made of copper.

As shown in FIG. 5b and FIG. 5c, the plate-type heat dissipation device 130 is disposed between the first circuit board 110 and the second circuit board 120, abutting the first ground layer 112 and the second ground layer 122 respectively. It is understood that the plate-type heat dissipation device 130 may be a plate-type heat pipe, a copper plate, a plate-type copper block, a micro fin, a water-cooling device, or a vapor chamber.

As shown in FIGS. 5a-5c, the flat cable 140 connects the first circuit board 110 and the second circuit board 120 so that the first circuit board 110 and the second circuit board 120, providing communicability therebetween.

To manufacture the function module 100, the first circuit board 110 is firstly coupled to the second circuit board 120 via the flat cable 140 as shown in FIG. 5a. Then, the first ground layer 112 of the first circuit board 110 faces the second ground layer 122 of the second circuit board 120 as shown in FIG. 5b. Finally, the plate-type heat dissipation device 130 is disposed between the first circuit board 110 and the second circuit board 120 to obtain the function module 100 as shown in FIG. 5c.

Furthermore, the function module 100 may further include a heat dissipation fin 150 as shown in FIG. 5b and FIG. 5c. The heat dissipation fin 150 is connected to the plate-type heat dissipation device 130 to dissipate heat therefrom. In addition, the function module 100 may further include a fan (not shown). The fan can be connected to the heat dissipation fin 150 to further dissipate heat from the function module 100.

Referring to FIG. 5d, the function module 100 may further include a first adhesion layer 116 and a second adhesion layer 126. The first adhesion layer 116 is disposed between the plate-type heat dissipation device 130 and the first ground layer 112, and combines the plate-type heat dissipation device 130 with the first circuit board 110. The second adhesion layer 126 is disposed between the plate-type heat dissipation device 130 and the second ground layer 122, and combines the plate-type heat dissipation device 130 with the second circuit board 120.

It is understood that both the first adhesion layer 116 and the second adhesion layer 126 may be made of brazing solder, tin solder, thermal interface material, or grease.

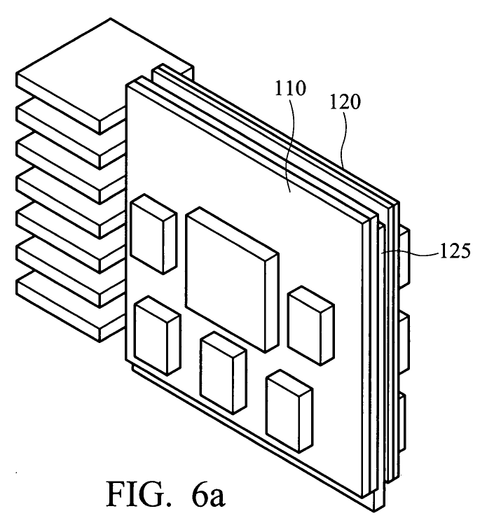

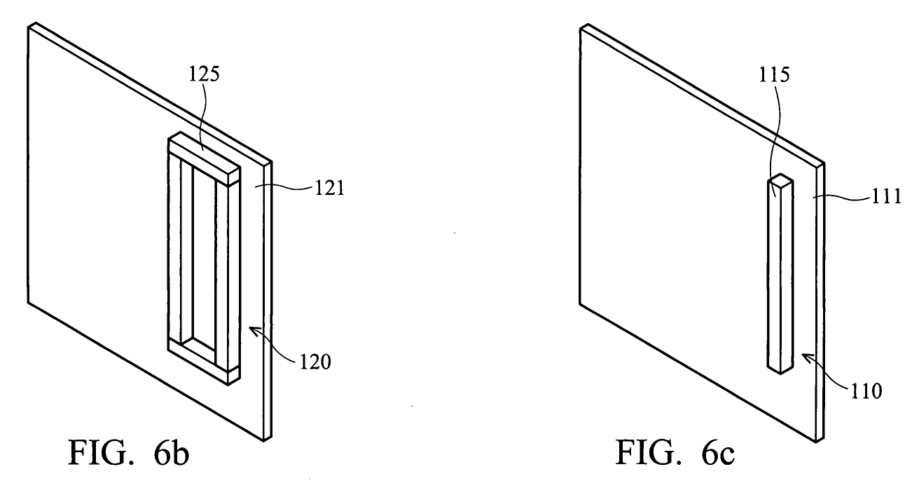

In addition, the first circuit board 110 may be coupled to the second circuit board without the flat cable. As shown in FIGS. 6a-6c, the first circuit board 110 includes a first connector 115 on the first surface 111, and the second circuit board 120 includes a second connector 125, corresponding to the first connector 115, on the second surface 121. The first circuit board 110 and the second circuit board 120 communicate with each other by the first connector 115 connecting to the second connector 125. The function module 100 can constitute the plate-type heat dissipation device attaching the first circuit board 110 to the second circuit board 120.

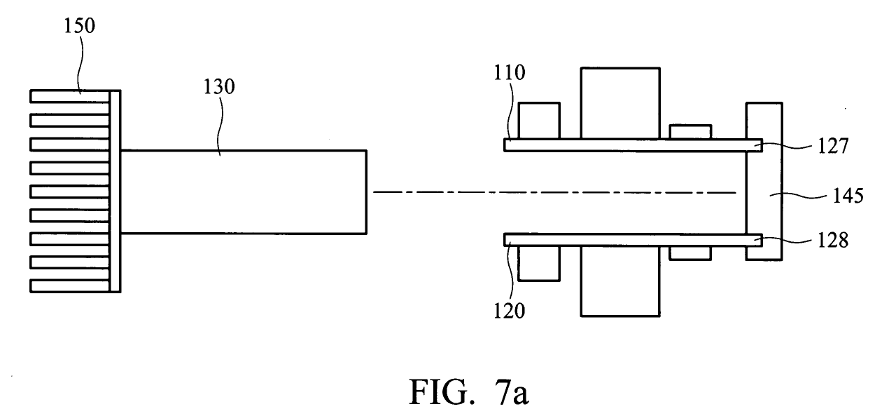

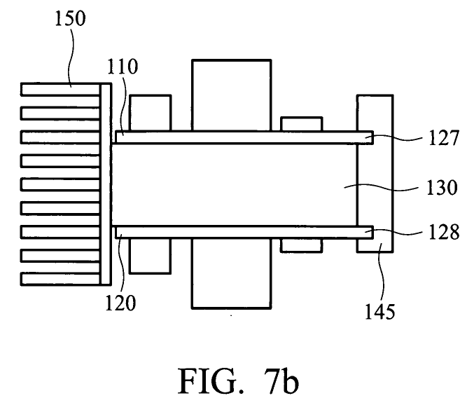

The first circuit board 110 may be coupled to the second circuit board by a slot connector 145. For example, as shown in FIG. 7a and FIG. 7b, a first contact 127 is disposed at a side of the first circuit board 110, and a second contact 128 is disposed at a side of the second circuit board 120. Both the first circuit board 110 and the second circuit board 120 can be communicated and fixed by the slot connector 145. The function module 100 can constitute the plate-type heat dissipation device attaching the first circuit board 110 to the second circuit board 120.

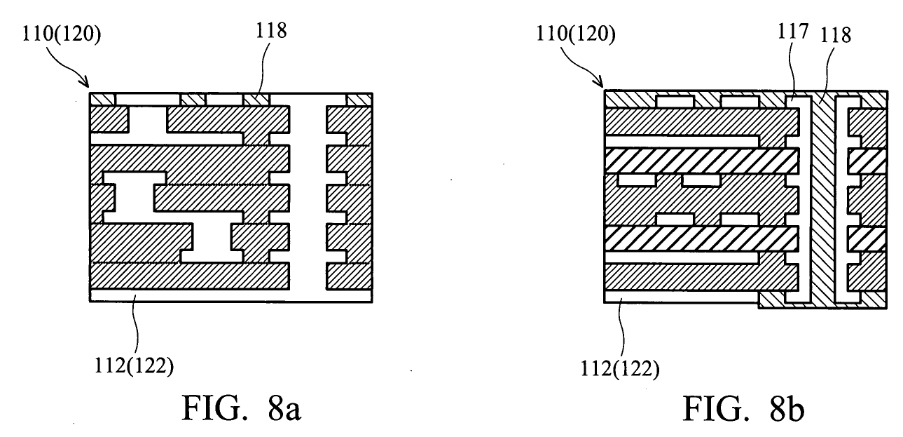

Furthermore, both the first circuit board 110 and the second circuit board 120 may be manufactured by forming blind holes on a copper plate (or a metal plate) in a build-up method as shown in FIG. 8a. In addition, as shown in FIG. 8b, both the first circuit board 110 and the second circuit board 120 may be manufactured by forming a through hole 117 on the printed circuit board. To prevent the tin solder from entering into the through hole 117 during manufacture, the through hole 117 is partially covered by a solder mask 118. Thus, the non-ground hole is protected from short circuit.

As stated above, the function module includes two circuit boards, each including a ground surface. By combining the plate-type heat dissipation device with the flat ground surfaces, a function module with a sandwich-type structure is obtained. Heat from the function module can thus be quickly and uniformly conducted to the plate-type heat dissipation device. Furthermore, heat from the function module can also be dissipated by the heat dissipation fin and the fan. In addition, both of the circuit boards can communicate with each other by the connectors or the flat cable.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A function module comprising:
a first circuit board including a first surface, with a first ground layer formed thereon;
a second circuit board, coupled to the first circuit board, including a second surface facing the first surface, wherein a second ground layer is formed on the second surface; and
a plate-type heat dissipation device, disposed between the first circuit board and the second circuit board, abutting the first ground layer and the second ground layer respectively.

2. The function module as claimed in claim 1, wherein the first circuit board further includes a third surface, opposite to the first surface, with a first device located thereon.

3. The function module as claimed in claim 1, wherein the second circuit board further includes a fourth surface, opposite to the second surface, with a second device located thereon.

4. The function module as claimed in claim 1, wherein the first ground layer comprises a copper layer.

5. The function module as claimed in claim 1, wherein the second ground layer comprises a copper layer.

6. The function module as claimed in claim 1, further comprising a flat cable connecting the first circuit board and the second circuit board, providing communicability therebetween.

7. The function module as claimed in claim 1, wherein the first circuit board includes a first connector, the second circuit board includes a second connector corresponding to the first connector, and the first circuit board and the second circuit board communicate with each other by the respective connectors.

8. The function module as claimed in claim 7, wherein the first connector is located on the first surface, and the second connector is located on the second surface.

9. The function module as claimed in claim 1, further comprising a slot connector connecting the first circuit board and the second circuit board, providing communicability therebetween.

10. The function module as claimed in claim 1, wherein the plate-type heat dissipation device is a plate-type heat pipe, a copper plate, a plate-type copper block, a micro fin, a water-cooling device, or a vapor chamber.

11. The function module as claimed in claim 1, further comprising a heat dissipation fin, connected to the plate-type heat dissipation device, for further dissipation of heat therefrom.

12. The function module as claimed in claim 11, further comprising a fan, connected to the heat dissipation fin, for further dissipation of heat therefrom.

13. The function module as claimed in claim 1, further comprising:
a first adhesion layer, disposed between the plate-type heat dissipation device and the first ground layer, for combining the plate-type heat dissipation device with the first circuit board; and
a second adhesion layer, disposed between the plate-type heat dissipation device and the second ground layer, for combining the plate-type heat dissipation device with the second circuit board.

14. The function module as claimed in claim 13, wherein both the first adhesion layer and the second adhesion layer comprise one selected from the group consisting of brazing solder, tin solder, thermal interface material, grease and the combination thereof respectively.

15. A function module comprising:
a first circuit board including a first surface with a first heat conduction layer formed thereon;
a second circuit board, coupled to the first circuit board, including a second surface facing the first surface, on which a second heat conduction layer is formed; and
a plate-type heat dissipation device, disposed between the first circuit board and the second circuit board, abutting the first heat conduction layer and the second heat conduction layer respectively.

16. The function module as claimed in claim 15, wherein the first heat conduction layer is a ground layer of the first circuit board, and the second heat conduction layer is a ground layer of the second circuit board.

17. The function module as claimed in claim 15, wherein the first circuit board further includes a third surface, opposite to the first surface, with a first device located thereon.

18. The function module as claimed in claim 15, wherein the second circuit board further includes a fourth surface, opposite to the second surface, with a second device located thereon.

19. The function module as claimed in claim 15, wherein the first heat conduction layer comprises a copper layer.

20. The function module as claimed in claim 15, wherein the second heat conduction layer comprises a copper layer.

21. The function module as claimed in claim 15, further comprising a flat cable connecting the first circuit board and the second circuit board, providing communicability therebetween.

22. The function module as claimed in claim 15, wherein the first circuit board includes a first connector, the second circuit board includes a second connector corresponding to the first connector, and the first circuit board and the second circuit board communicate with each other by the respective connectors.

23. The function module as claimed in claim 22, wherein the first connector is located on the first surface, and the second connector is located on the second surface.

24. The function module as claimed in claim 15, further comprising a slot connector connecting the first circuit board and the second circuit board, providing communicability therebetween.

25. The function module as claimed in claim 15, wherein the plate-type heat dissipation device is a plate-type heat pipe, a copper plate, a plate-type copper block, a micro fin, a water-cooling device, or a vapor chamber.

26. The function module as claimed in claim 15, further comprising a heat dissipation fin, connected to the plate-type heat dissipation device, for dissipating heat therefrom.

27. The function module as claimed in claim 26, further comprising a fan, connected to the heat dissipation fin, for dissipating heat therefrom.

28. The function module as claimed in claim 15, further comprising:
a first adhesion layer, disposed between the plate-type heat dissipation device and the first heat conduction layer, attaching the plate-type heat dissipation device to the first circuit board; and
a second adhesion layer, disposed between the plate-type heat dissipation device and the second heat conduction layer, attaching the plate-type heat dissipation device to the second circuit board.

29. The function module as claimed in claim 28, wherein both the first adhesion layer and the second adhesion layer comprise one selected from the group consisting of brazing solder, tin solder, thermal interface material, or grease and the combination thereof respectively.
